(19) United States
(12) Patent Application Publication
(10) Pub. No.: US 2012/0245871 A1
(43) Pub. Date: Sep. 27, 2012

(54) BATTERY TESTER WITH HIGH PRECISION

(76) Inventors: Hsien-Fang Sheng, Taipei (TW); Yuan-Chen Hsiao, Taipei (TW)

(21) Appl. No.: 13/069,033

(22) Filed: Mar. 22, 2011

(51) Int. Cl. G01R 31/36

(52) U.S. Cl. 702/63

(57) ABSTRACT

The battery tester has a casing having an input device and two detecting wires, a microprocessor, a loading unit and a battery power status detecting unit. The microprocessor builds a strategic decision process therein to determine a loading time for a battery according to the battery capacity, battery voltage and detection requirements having 1/N CCA and a loading time input from the input device. Therefore, the battery tester detects batteries with different capacities and has accurate detecting results.

### BACKGROUND OF THE INVENTION

1. Field of the Invention

The present invention relates to the field of a battery tester, and more particularly to a battery tester with high precision.

2. Description of Related Art

There are many types of the rechargeable battery with different capacities on the market. The battery tester is used to detect the residual capacity of the rechargeable battery to determine the health of the rechargeable battery. However, the conventional battery tester uses only one method to detect different rechargeable batteries and inaccurate testing result will likely occur.

In general, the conventional battery tester uses 1/2 Cold Cranking Amps (hereinafter CCA) testing method to detect the health of the rechargeable battery, the method having steps of: (a) adding a load to the two electrodes of the battery to discharge the battery by loading the amperes of 1/2 CCA for 15 seconds; and (b) determining the health of the battery according to the discharging diagram.

In the conventional testing method implemented by the battery tester, the resistance of the load and the duration of adding load to the battery are fixed. Therefore, when the battery tester respectively detects rechargeable batteries with different capacities, figures of the discharging diagrams are not precise. The testing precision of the conventional battery tester is not ideal for all rechargeable batteries.

To overcome the shortcomings, the present invention provides a battery tester with high precision to mitigate or obviate the aforementioned problems.

### SUMMARY OF THE INVENTION

Based on the foregoing drawbacks of the conventional battery tester, the main objective of the present invention is to provide a battery tester with high precision.

The battery tester has a casing having an input device and two detecting wires, a microprocessor, a loading unit and a battery power status detecting unit. The microprocessor builds a strategic decision process therein to determine a loading time for a battery according to the battery capacity, battery voltage and detection requirements having 1/N CCA and a loading time input from the input device. Therefore, the battery tester detects batteries with different capacities and has accurate detecting results.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a battery tester in accordance with the present invention;

FIG. 2 is a functional block diagram of a battery tester in accordance with the present invention;

FIG. 3 is a flow chart of a strategic decision process implemented in FIG. 1;

FIG. 4 is a testing diagram of the battery tester in accordance with the present invention; and

FIG. 5 is a flow chart of a detecting process in accordance with the present invention.

### DETAILED DESCRIPTION OF THE PREFERRED EMBODIMENT

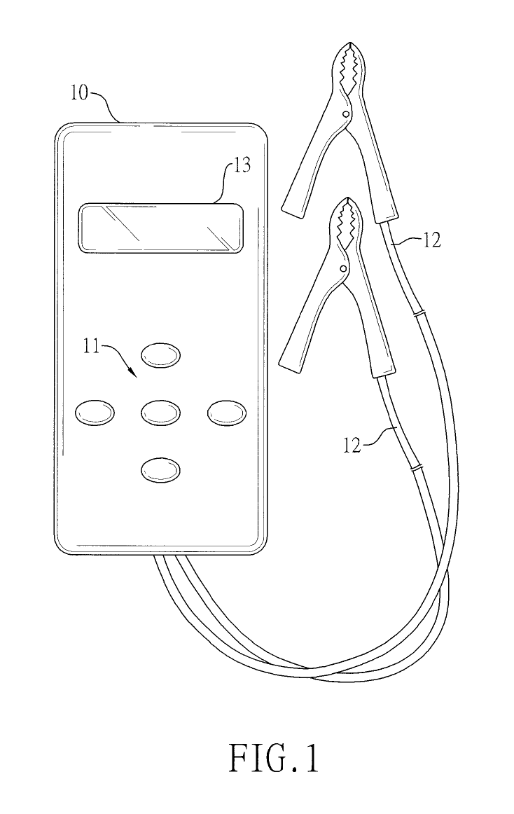

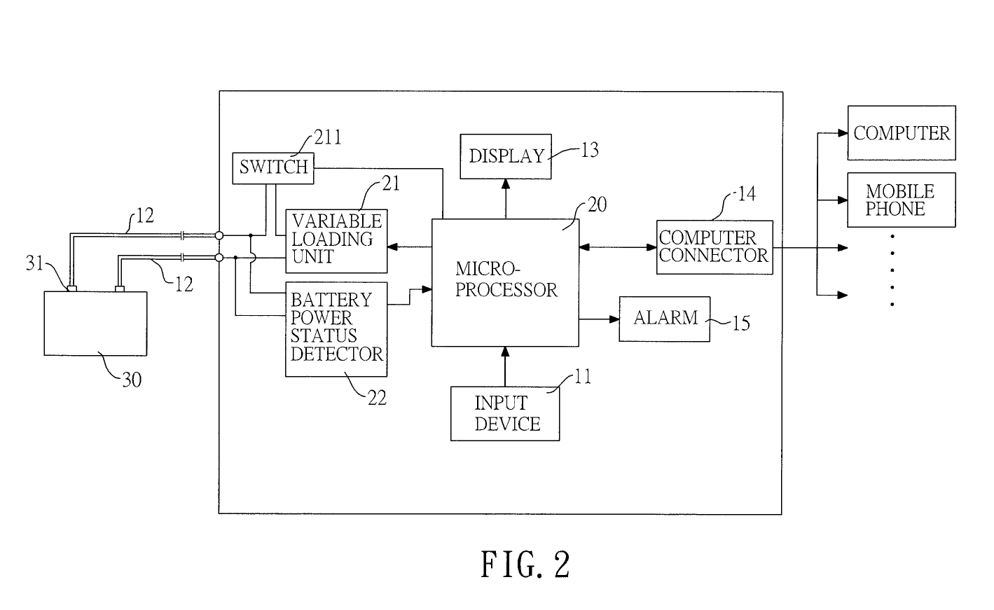

With reference to FIGS. 1 and 2, a preferred embodiment of a battery tester with high precision in accordance with the present invention has a casing 10, a microprocessor 20, a loading unit 21, a switch 211 and a battery power status detecting unit 22.

The casing 10 has an input device 11 and two detecting wires 12. A user uses the input device 11 to select a specific battery capacity. The detecting wires 12 are respectively and electronically connected to two electrodes 31 of the battery 30. In the preferred embodiment, the two detecting wires 12 respectively clip to the two electrodes 31 of the battery 30. In addition, the casing 10 further has a display 13, a computer connector 14 and an alarm 15. The computer connector 14 is used to connect to an external electronic device such as a computer or mobile phone.

The microprocessor 20 builds a strategic decision process and a detecting process therein.

The loading unit 21 is electronically connected to the microprocessor 20 and the two wires 12. The loading unit is electronically connected to the electrodes 31 of the battery 30 through the two wires 12 to detect voltage and current changes of the battery 30 and then responds with the voltage and current values to the microprocessor 20.

The switch 211 is electronically connected between one of the detecting wires 12 and the loading unit 21 and is controlled by the microprocessor 20.

The battery power status detecting unit 22 is electronically connected between the detecting wires 12 and the microprocessor 20 to detect the battery voltage value and/or current value. Further, the battery power status detecting unit 22 may be built-in the microprocessor 20.

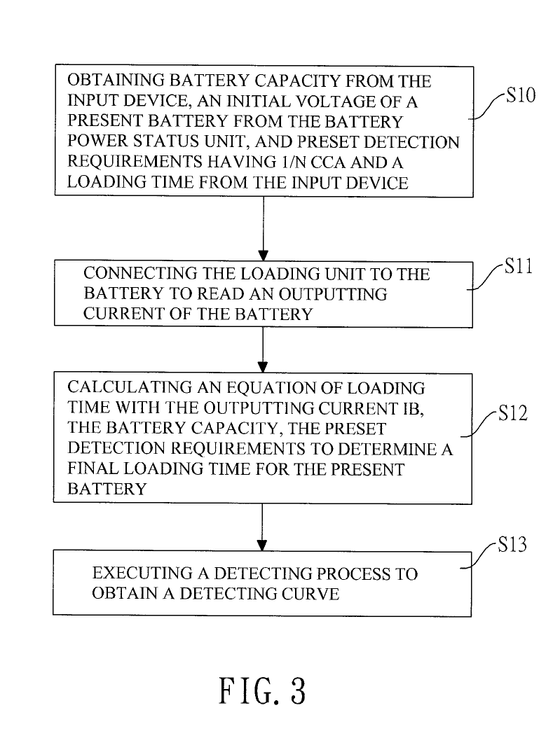

With further reference to FIG. 3, the strategic decision process has the following steps of:

(a) obtaining battery capacity (CCA_{B}) from the input device 11, a battery voltage (V_{B}) of a present battery 30 from the battery power status unit 22, and the preset detection requirements having 1/N CCA and a loading time (T_{LOAD}) from the input device 11 (S10);

(b) connecting the loading unit 21 to the battery 30 to read an outputting current I_{B} of the battery 30 (S11);

(c) calculating an equation of loading time with the outputting current I_{B}, the battery capacity, the preset detection requirements to determine a final loading time for the present battery 30 (S12), wherein the equation is

$$\frac{( {CCA}_{B} \times \frac{1}{N} )}{{I}_{B}} \times {T}_{LOAD} ,$$

and

(d) executing a detecting process to obtain a detecting curve (S13).

### Example 1

If the user detects the health of the present battery 30 with 12 V/1000 CCA, the preset detection requirements (1/2CCA, 15 sec) and the loading unit 21 with a fixed resistance (0.12 ohm). The microprocessor 20 previously turns on the switch 211 so the loading unit 21 is connect to the battery 30. Then the microprocessor 20 obtains the outputting current (I_{B}=100 A). Since the batteries with different capabilities require different loading times, the processor 20 calculates the equation of loading time:

$$\frac{( 1000 \times \frac{1}{2} )}{100} \times 15 = 75 sec .$$

Therefore, the proper final loading time for the present battery 30 with the 12V /1000 CCA is 75 sec.

### Example 2

If the user detects the health of the present battery 30 with 12 V/900 CCA, the preset detection requirements (1/3CCA, 20 sec) and the loading unit 21 with a fixed resistance (0.08 ohm). The microprocessor 20 previously turns on the switch 211 so the loading unit 21 connects to the battery 30. Then the microprocessor 20 obtains the outputting current (I_{B}=150 A). The processor 20 calculates the equation of loading time:

$$\frac{( 900 \times \frac{1}{3} )}{150} \times 20 = 40 sec .$$

Therefore, the proper final loading time for the present battery 30 with the 12V /900 CCA is 40 sec.

Based on the two examples, the battery tester uses a fixed loading unit, but the final loading time is determined according to the capability of the battery and the preset detection requirements. In the detecting process, the battery can continuously discharge for the final loading time and the microprocessor obtains enough discharging power status and a high precision detecting curve to analyze the health of the battery according to the detecting curve.

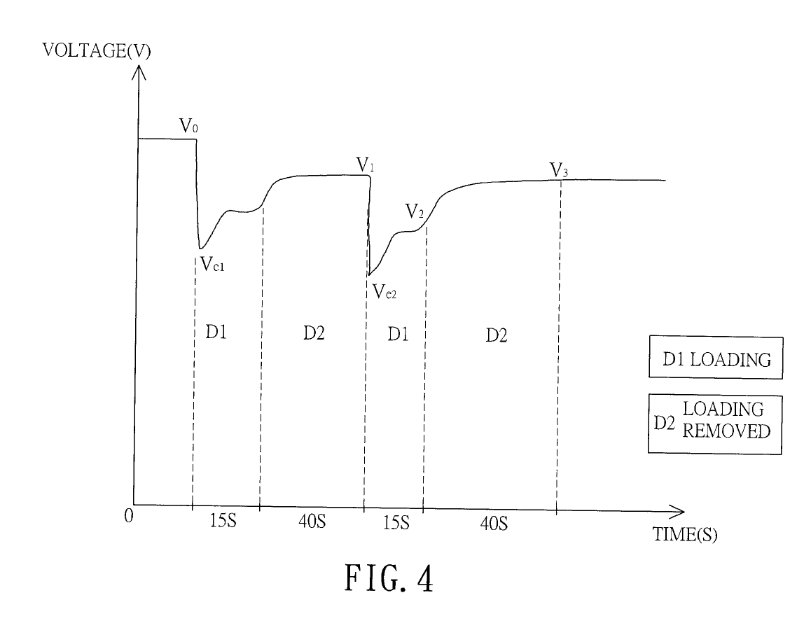

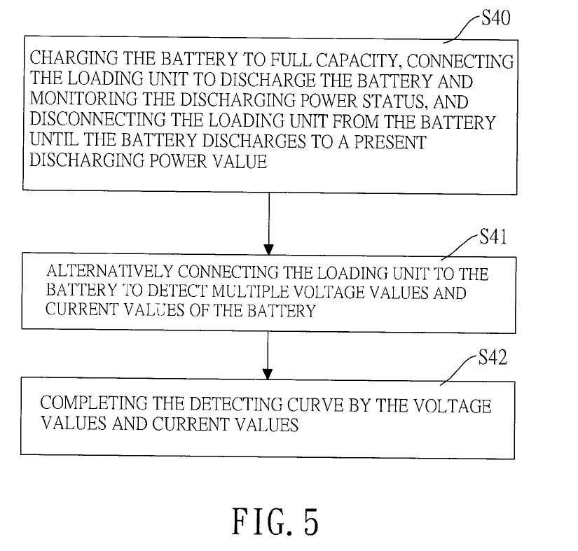

With reference to FIGS. 1, 4 and 5, the detecting curve obtained by the microprocessor 20 and the flow chart of the detecting process are shown. In detecting process, the battery 30 is first charged to full capacity and just removed from a charger. The loading unit 21 is then connected to the battery 30. The microprocessor 20 detects a discharging power of the battery 30 through the loading unit 21 and monitors whether a discharging power of the battery 30 achieves a present power vale (Vₑ₂). When the discharging power achieves the present power value, the switch 211 are removed from the battery 30 so the loading unit 21 is disconnected from the battery (S20). Therefore, the battery 30 has no floating charging voltage. Then, the loading unit 21 is alternatively connected to the battery 30 to detect multiple voltage values and current values of the battery 30 (S21). Finally, the detecting curve is completed by the voltage values and/or current values and the microprocessor determines the health of the battery according to the detecting curve (S22).

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A battery tester with high precision, comprising:
a casing having:
an input device providing different options of battery capacities and detection requirements; and
two detecting wires adapted to selectively connect to two electrodes of a battery;
a microprocessor building a strategic decision process therein;
a loading unit electronically connected to the microprocessor and connected to the detecting wires;
a switch electronically connected between one of the detecting wires and the loading unit, and controlled by the microprocessor; and
a battery power status detecting unit electronically connected to the microprocessor to detect a voltage and current of the battery and reporting the voltage and current to the microprocessor;
wherein the strategic decision process comprises steps of:
(a) obtaining battery capacity (CCA_{B}) from the input device , a battery voltage (V_{B}) of a present battery from the battery power status unit, and preset detection requirements having 1/N CCA and a loading time (T_{LOAD}) from the input device 11;
(b) connecting the loading unit to the battery to read an outputting current I_{B} of the battery;
(c) calculating an equation of loading time with the outputting current I_{B}, the battery capacity, the preset detection requirements to determine a final loading time for the present battery, wherein the equation is
$$\frac{( {CCA}_{B} \times \frac{1}{N} )}{{I}_{B}} \times {T}_{LOAD} ,$$
and
(d) executing a detecting process to obtain a detecting curve.

2. The battery tester as claimed in claim 1, wherein the microprocessor further builds a detecting process having steps of:
(a) charging the battery to full capacity and just removed from a charger;
(b) connecting the loading unit to discharge the battery and monitoring the discharging power status;
(c) disconnecting the loading unit from the battery until the battery discharges to a present discharging power value;
(d) alternatively connecting the loading unit to the battery to detect multiple voltage values and current values of the battery; and
(e) completing the detecting curve by the voltage values and current values.

3. The battery tester as claimed in claim 2, wherein the casing further comprises a display, a computer connector and an alarm.
